(19) United States
(12) Patent Application Publication
(10) Pub. No.: US 2015/0156897 A1
(43) Pub. Date: Jun. 4, 2015

(54) DISPLAY DEVICE

(71) Applicant: Mitsubishi Electric Corporation, Tokyo (JP)

(72) Inventors: Eri MORIMOTO, Kumamoto (JP); Mitsuo YAMASHITA, Kumamoto (JP)

(73) Assignee: Mitsubishi Electric Corporation, Tokyo (JP)

(21) Appl. No.: 14/554,761

(22) Filed: Nov. 26, 2014

(30) Foreign Application Priority Data
Dec. 4, 2013 (JP) 2013-250786

(51) Int. Cl. H05K 5/02; H05K 5/03; H05K 5/00

(52) U.S. Cl. CPC H05K 5/02; H05K 5/0017; H05K 5/03

(57) ABSTRACT

A display device includes an adhesive member disposed between a display surface of a display panel and a protective cover such that the adhesive member is in contact with the display surface of the display panel and the protective cover. The adhesive member is disposed over a region ranging from the inside of the opening to an upper surface of an opening-side edge portion which is an edge portion of a frame and is in contact with the opening. A recessed portion which reduces a stress generated in the adhesive member due to a contact of the adhesive member with the opening-side edge portion is formed on the opening-side edge portion.

### BACKGROUND OF THE INVENTION

1. Field of the Invention

The present invention relates to a display device provided with a protective cover.

2. Description of the Background Art

With respect to a display device installed outdoors, it is necessary to protect a display panel which the display device includes from an impact from the outside, intrusion of water due to rains, or the like. For this end, a display surface of the display panel is, in general, covered with a transparent protective cover made of a resin or glass. The display surface is a screen on which an image is displayed. Further, it is often the case where water proofing is applied to a peripheral portion of the protective cover of the display device. The display device is, for example, a liquid crystal display device which displays an image using liquid crystal.

When the protective cover is disposed so as to cover the display surface of the display panel, an air layer is generated between the display panel and the protective cover. Accordingly, an external light which is incident on the display surface reflects on a front surface and a back surface of the transparent protective cover and a front surface of the display panel which is a flat panel. As a result, there arises a drawback that visibility of an image displayed on the display surface is lowered.

Japanese Patent Application Laid-Open No. 2006-290960 discloses a technique for enhancing visibility (hereinafter also referred to as the related art A). To be more specific, in the related art A, a transparent member is disposed between a display panel and a protective cover. The transparent member is, for example, a light transmissive adhesive sheet, a transparent resin or the like. Hereinafter, the light transmissive adhesive sheet is also referred to as a transparent adhesive sheet.

With respect to the protective cover, there may be the case where a coating layer having a thickness is formed on a portion of the protective cover which overlaps with an adhesive surface adhered to the display panel (for example, a region around the display surface of the display panel). The coating layer is, for example, a printing layer or the like. Further, for example, there may be also the case where a coating layer is formed also on the portion of the protective cover where the coating layer overlaps with a region outside an operation area of a touch panel.

When such a protective cover is used, a portion of the transparent adhesive sheet which overlaps with the coating layer is pressed. Accordingly, a stress is generated at a portion which overlaps with the coating layer. As a result, there arises a drawback that the display panel or the protective cover is peeled off.

Japanese Patent Application Laid-Open No. 2012-008294 discloses a technique for alleviating (reducing) a stress generated in a transparent adhesive sheet (hereinafter also referred to as related art B). To be more specific, in the related art B, a recessed portion is formed in a coating layer of a protective cover which overlaps with the transparent adhesive sheet. Due to such a constitution, a stress generated in the transparent adhesive sheet is alleviated. As a result, a force which may peel off the transparent adhesive sheet can be suppressed.

In general, a display panel having a display surface is covered with a frame having an opening. For example, in the display panel, the display surface is exposed through the opening at a peripheral portion of the display surface. Further, a frame is fixed to the display panel above the peripheral portion such that the frame covers the peripheral portion. Due to such a constitution of the frame, a stepped portion is formed between the frame and the display surface of the display panel. Hereinafter, an edge portion of the frame which is brought into contact with the opening is also referred to as an opening-side edge portion.

When an adhesive member having a size larger than a size of the display surface of the display panel is adhered to the display surface of the display panel to which the frame is fixed, the adhesive member is disposed over an upper surface of the opening-side edge portion extending from the inside of the opening. The adhesive member is, for example, a transparent adhesive sheet. When the display panel and the protective cover are adhered to each other by way of the adhesive member in such a state, a stress is generated in the adhesive member disposed on the upper surface of the opening-side edge portion.

Accordingly, due to a stress generated in the adhesive member disposed between the display surface of the display panel and the protective cover, the following drawbacks arise. The drawback may be, for example, a drawback that the display panel or the protective cover is peeled off. In the related art B, countermeasures to overcome the above-mentioned drawbacks in a state where the adhesive member is disposed on the upper surface of the opening-side edge portion of the frame are not taken into account at all.

### SUMMARY OF THE INVENTION

Accordingly, it is an object of the present invention to dispose a display device which can reduce the occurrence of drawbacks caused by a stress generated in a state where an adhesive member is disposed on an upper surface of an edge portion of a frame.

A display device according to an aspect of the present invention includes: a display panel having a display surface on which an image is displayed; a frame which holds the display panel, the frame having an opening formed therein, the opening being formed so as to expose the display surface to the outside of the frame as viewed in a plan view; a protective cover having light transmitting property and formed so as to cover the display surface; and an adhesive member having light transmitting property and disposed between the display surface and the protective cover such that the adhesive member is in contact with the display surface and the protective cover, wherein the adhesive member is disposed over a region ranging from the inside of the opening to an upper surface of an opening-side edge portion which is an edge portion of the frame and is in contact with the opening, and a stress reducing portion which reduces a stress generated in the adhesive member due to a contact of the adhesive member with the opening-side edge portion is formed on the opening-side edge portion.

According to the present invention, the display device includes the adhesive member disposed between the display surface of the display panel and the protective cover in a state where the adhesive member is in contact with the display surface of the display panel and the protective cover. The adhesive member is disposed over a region ranging from the inside of the opening to an upper surface of an opening-side edge portion which is an edge portion of the frame and is in contact with the opening. A stress reducing portion which reduces a stress generated in the adhesive member due to a contact of the adhesive member with the opening-side edge portion is formed on the opening-side edge portion.

Accordingly, it is possible to reduce the occurrence of drawbacks caused by a stress generated in a state where the adhesive member is disposed on the upper surface of the edge portion of the frame.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a display device according to a first preferred embodiment of the present invention;

FIG. 2 is a cross-sectional view of the display device according to the first preferred embodiment of the present invention;

FIG. 3 is a cross-sectional view of a display device according to a modification of the first preferred embodiment of the present invention;

FIG. 4 is a cross-sectional view of a display device according to a second preferred embodiment of the present invention;

FIG. 5 is a cross-sectional view of a display device according to a third preferred embodiment of the present invention;

FIG. 6 is a plan view of a display device according to a fourth preferred embodiment of the present invention;

FIG. 7 is an enlarged view of a portion of the display device according to the fourth preferred embodiment of the present invention;

FIG. 8 is a cross-sectional view of a display device according to a fifth preferred embodiment of the present invention; and

FIG. 9 is a cross-sectional view of a display device according to a sixth preferred embodiment of the present invention.

### DESCRIPTION OF THE PREFERRED EMBODIMENTS

Hereinafter, preferred embodiments of the present invention are described by reference to drawings. In the description made hereinafter, identical constitutional elements are given the same symbols. The identical constitutional elements are also given the same names and have the same functions. Accordingly, in some embodiments, the detailed description of such constitutional elements is omitted.

Sizes, materials, shapes, the relative arrangement and the like of the respective constitutional elements exemplified in the preferred embodiments are appropriately changed depending on the constitution of the device to which the present invention is applied and various conditions, and the present invention is not limited to the exemplified cases. Further, sizes of the respective constitutional elements in the respective drawings may differ from actual sizes of the respective constitutional elements.

### First Preferred Embodiment

FIG. 1 is a plan view of a display device 100 according to a first preferred embodiment of the present invention. In FIG. 1, the X direction, the Y direction and the Z direction are orthogonal to each other. The X direction, the Y direction and the Z direction described in the following drawings are also orthogonal to each other. In the description made hereinafter, the direction including the X direction and the direction opposite to the X direction (−X direction) is also referred to as the X axis direction. In the description made hereinafter, the direction including the Y direction and the direction opposite to the Y direction (−Y direction) is also referred to as the Y axis direction. In the description made hereinafter, the direction including the Z direction and the direction opposite to the Z direction (−Z direction) is also referred to as the Z axis direction.

In the description made hereinafter, a plane including the X axis direction and the Y axis direction is also referred to as an XY plane. In the description made hereinafter, a plane including the X axis direction and the Z axis direction is also referred to as an XZ plane. In the description made hereinafter, a plane including the Y axis direction and the Z axis direction is also referred to as a YZ plane.

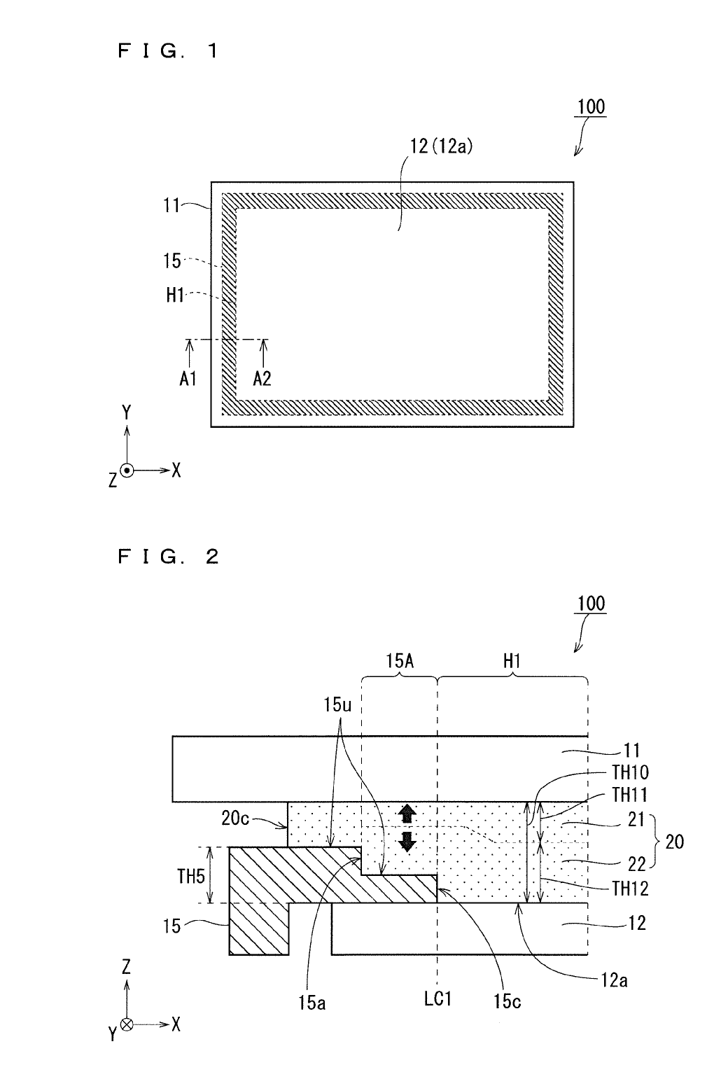

FIG. 2 is a cross-sectional view of the display device 100 according to the first preferred embodiment of the present invention. To be more specific, FIG. 2 is a cross-sectional view of the display device 100 taken along a line A1-A2 in FIG. 1. The display device 100 is a liquid crystal display device which displays an image thereon by making use of liquid crystal, for example. The display device 100 is not limited to the liquid crystal display device, and may be display devices with other display systems.

Referring to FIG. 1 and FIG. 2, the display device 100 includes: a protective cover 11; a display panel 12; a frame 15; and an adhesive member 20.

The display panel 12 has a display surface 12a on which an image is displayed. The display panel 12 is a liquid crystal display panel, for example. The display panel 12 is configured such that two insulating substrates are adhered to each other with a liquid crystal material sandwiched therebetween, for example. A drive circuit for driving liquid crystal, a circuit board (not shown) and the like are mounted on the display panel 12. The display panel 12 may be a touch panel having a function of receiving a touch operation performed by a user.

As shown in FIG. 1, a surface light source device (not shown) is mounted on a surface (back surface) of the display panel 12 opposite to the display surface 12a. To be more specific, as shown in FIG. 2, the surface light source device (not shown) which emits light in the Z direction is disposed below the display panel 12. The surface light source device is held by the frame 15. For example, the surface light source device is fitted in the frame 15. For the sake of simplification of the drawing, the constitution of the display panel, the drive circuit, the circuit board and the surface light source device are not shown in FIG. 2.

The display panel 12 is not limited to a liquid crystal panel, and display panels adopting other systems may also be used as the display panel 12.

An opening H1 is formed in the frame 15. To be more specific, the opening H1 is formed so as to expose the display surface 12a to the outside of the frame 15 as viewed in a plan view. In the description made hereinafter, an edge portion of the frame 15 which is in contact with the opening H1 is also referred to as an opening-side edge portion.

The frame 15 is fixed to the display panel 12 such that the frame 15 holds the display panel 12. To be more specific, the frame 15 holds the display panel 12 such that the opening-side edge portion covers a peripheral portion of the display surface 12a of the display panel 12.

The protective cover 11 has light transmitting property. The protective cover 11 is disposed so as to cover the display surface 12a exposed through the opening H1. The display surface 12a is protected by the protective cover 11.

The adhesive member 20 has light transmitting property. The adhesive member 20 is a transparent adhesive sheet, for example. As shown in FIG. 2, the adhesive member 20 is disposed between the display surface 12a and the protective cover 11 such that the adhesive member 20 is in contact with the display surface 12a and the protective cover 11. That is, the adhesive member 20 is disposed in a gap defined between the display surface 12a and the protective cover 11. The display surface 12a of the display panel 12 and the protective cover 11 are adhered to each other by the adhesive member 20.

A size of the adhesive member 20 as viewed in a plan view is larger than a size of the opening H1 as viewed in a plan view. To be more specific, the size of the adhesive member 20 in the XY plane is larger than the size of the opening H1 in the XY plane.

Although there may be a case where a coating layer is formed on the protective cover 11, in order to facilitate the understanding, the illustration of the coating layer is omitted in FIG. 2. The coating layer is a printing layer having a predetermined thickness, for example. In the display panel 12, the coating layer is formed on a peripheral edge portion of a main surface including the display surface 12a, for example. The main surface of the display panel 12 is a surface of the display panel 12 where the display surface 12a is formed. The peripheral edge portion of the main surface of the display panel 12 is a peripheral region of the display surface 12a, for example. The peripheral region of the display surface 12a is a region of the main surface which does not include the display surface 12a. The peripheral edge portion of the main surface of the display panel 12 is a peripheral region of an operation area of the touch panel (a region corresponding to the display surface 12a), for example.

The adhesive member 20 is constituted of an adhesive member 21 and an adhesive member 22. That is, the adhesive members 21, 22 are disposed between the protective cover 11 and the display panel 12. The adhesive members 21, 22 have a sheet shape respectively. The adhesive member 20 is formed by adhering the adhesive member 21 and the adhesive member 22 to each other, for example.

The adhesive member 22 is disposed on the display surface 12a. That is, the adhesive member 22 is in contact with the display surface 12a through the opening H1. The adhesive member 21 is disposed on the adhesive member 22. The adhesive member 21 is in contact with the protective cover 11.

A size of the adhesive member 21 as viewed in a plan view is larger than the size of the opening H1 as viewed in a plan view. To be more specific, the size of the adhesive member 21 in the XY plane is larger than the size of the opening H1 in the XY plane.

A size of the adhesive member 22 as viewed in a plan view is larger than the size of the opening H1 as viewed in a plan view. To be more specific, the size of the adhesive member 22 in the XY plane is larger than the size of the opening H1 in the XY plane.

In the description made hereinafter, a display device in the course of manufacture where the protective cover 11, the display panel 12, the frame 15 on which a recessed portion 15A described later is not formed, the adhesive member 20 and the like are arranged as shown in FIG. 1 and FIG. 2 is also referred to as a display device N. The display device N is a device having no recessed portion 15A.

To describe the display device N having no recessed portion 15A by reference to FIG. 1, in general, small spaces are present in the inside of the display surface 12a in the XY plane. The small spaces are air bubbles which are present in the adhesive member 20, for example.

To eliminate the small spaces, in general, an autoclave having a pressurization function is used with respect to the display device N. To be more specific, the autoclave applies pressurization treatment to the display device N. The pressurization treatment is a treatment where only pressurization is performed or a treatment where both heating and pressurization are performed. By performing the pressurization treatment, the small spaces and the like which are present in the display device N are removed.

In the description made hereinafter, an upper surface of the frame 15 is also referred to as an upper surface 15u.

In this preferred embodiment, as shown in FIG. 2, a recessed portion 15A is formed on the opening-side edge portion of the frame 15. By forming the recessed portion 15A on the opening-side edge portion, a stepped portion 15a is formed on the opening-side edge portion. Further, the adhesive member 20 is disposed over a region ranging from the inside of the opening H1 to the upper surface 15u of the opening-side edge portion. That is, the adhesive member 20 is disposed such that the adhesive member 20 extends over the upper surface 15u of the opening-side edge portion from the inside of the opening H1.

As shown in FIG. 2, the opening-side edge portion is a region ranging from a position LC1 of the frame 15 which is in contact with the opening H1 to an edge 20c of the adhesive member 20 disposed on the upper surface 15u. In other words, the opening-side edge portion is a region corresponding to an edge portion of the adhesive member 20 disposed on the upper surface 15u of the frame 15.

In the description made hereinafter, a thickness of the adhesive member 20 is also referred to as a thickness TH10. In the description made hereinafter, a thickness of the adhesive member 21 is also referred to as a thickness TH11. In the description made hereinafter, a thickness of the adhesive member 22 is also referred to as a thickness TH12. In the description made hereinafter, a thickness of the opening-side edge portion of the frame 15 is also referred to as a thickness TH5. The thickness TH5 is a thickness of a portion of the opening-side edge portion where the recessed portion 15A is not formed.

As shown in FIG. 2, the thickness TH10 of the adhesive member 20 is equal to or more than the thickness TH5 of the portion of the opening-side edge portion where the recessed portion 15A is not formed. The thickness TH12 of the adhesive member 22 is equal to or more than the thickness TH5 of the portion of the opening-side edge portion where the recessed portion 15A is not formed. That is, the thickness TH12 is equal to or larger than the thickness TH5.

The thickness TH12 of the adhesive member 22 is not limited to the above-mentioned thickness. The thickness TH12 may be smaller than the thickness TH5.

A thickness of a portion of the opening-side edge portion where the recessed portion 15A is formed is smaller than the thickness TH5 of the portion of the opening-side edge portion where the recessed portion 15A is not formed.

In a step of adhering the protective cover 11 and the display panel 12 which is held by the frame 15 having the constitution shown in FIG. 2 to each other by way of the adhesive member 20, a stress is generated in the adhesive member 20 due to a contact of the adhesive member 20 with the opening-side edge portion of the frame 15. In the description made hereinafter, a stress generated in the adhesive member 20 due to a contact of the adhesive member 20 with the opening-side edge portion is also referred to as a member stress. The member stress is also a stress generated in the adhesive member 21 and the adhesive member 22.

Accordingly, some of the member stress acts in the direction along which the protective cover 11 and the display panel 12 are away from each other (Z axis direction, the directions indicated by arrows in FIG. 2). Accordingly, as described above, small spaces are present in the inside of the display surface 12a of the display device N in the XY plane.

In view of the above, in this preferred embodiment, the recessed portion 15A is formed on the opening-side edge portion of the frame 15. Due to the presence of the recessed portion 15A, a member stress applied to the opening-side edge portion is reduced (alleviated) by an amount corresponding to a volume of the recessed portion 15A. That is, the recessed portion 15A is a stress reducing portion which reduces a member stress.

Accordingly, some of the member stress applied in the Z axis direction in FIG. 2 is reduced. Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

As described above, according to this preferred embodiment, the display device 100 includes the adhesive member 20 disposed between the display surface 12a and the protective cover 11 in a state where the adhesive member 20 is in contact with the display surface 12a of the display panel 12 and the protective cover 11. The adhesive member 20 is disposed over a region ranging from the inside of the opening H1 to the upper surface 15u of the opening-side edge portion which is the edge portion of the frame 15 and is in contact with the opening H1. The recessed portion 15A constituting the stress reducing portion which reduces a stress generated in the adhesive member 20 due to a contact of the adhesive member 20 with the opening-side edge portion is formed on the opening-side edge portion.

Due to such a constitution, it is possible to reduce the occurrence of drawbacks caused by a stress generated in a state where the adhesive member is disposed on the upper surface of the edge portion of the frame. One of these drawbacks may be, for example, the drawback that the display panel 12 or the protective cover 11 is peeled off.

In this preferred embodiment, due to the presence of the recessed portion 15A, a member stress applied to the opening-side edge portion is reduced (alleviated) by an amount corresponding to the volume of the recessed portion 15A. Accordingly, some of the member stress applied in the Z axis direction in FIG. 2 is reduced.

Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

Due to the presence of the recessed portion 15A, a member stress generated between the adhesive member 21 and the adhesive member 22 is also reduced. Accordingly, it is possible to prevent the intrusion of air bubbles (small spaces) between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the presence of the recessed portion 15A, a member stress generated in the adhesive member 22 is also reduced. Accordingly, in adhering the adhesive member 21 and the adhesive member 22 to each other, it is possible to prevent the presence of air bubbles between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the above-mentioned constitution, the display device 100 can easily realize the display of an image with high quality.

As described above, when the adhesive member having a size larger than a size of the display surface of the display panel is adhered to the display surface of the display panel to which the frame is fixed, the adhesive member is disposed over a region ranging from the inside of the opening to the upper surface of the opening-side edge portion. When the display panel and the protective cover are adhered to each other by way of the adhesive member in such a state, a stress is generated in the adhesive member disposed on the upper surface of the opening-side edge portion.

There may be a case where a coating layer having a predetermined thickness is formed on an adhesion surface of the protective cover which is adhered to the display panel. The adhesion surface is a surface of the protective cover which is adhered to a region of the display panel in the periphery of the display surface or a region of the touch panel in the periphery of an operation area, for example. The coating layer is a printing layer, for example. Also in this case, in the same manner as the above-mentioned cases, a stress is generated in the adhesive member disposed on the upper surface of the coating layer.

Accordingly, due to a stress generated in the adhesive member, the following drawbacks arise. One of these drawbacks may be, for example, a drawback that the display panel and the protective cover are peeled off. Another drawback may be, for example, a drawback that air remains in the adhesive member in the inside of the opening.

On the other hand, the display device 100 of this preferred embodiment has the above-mentioned constitution and hence, the display device 100 can overcome the above-mentioned drawbacks.

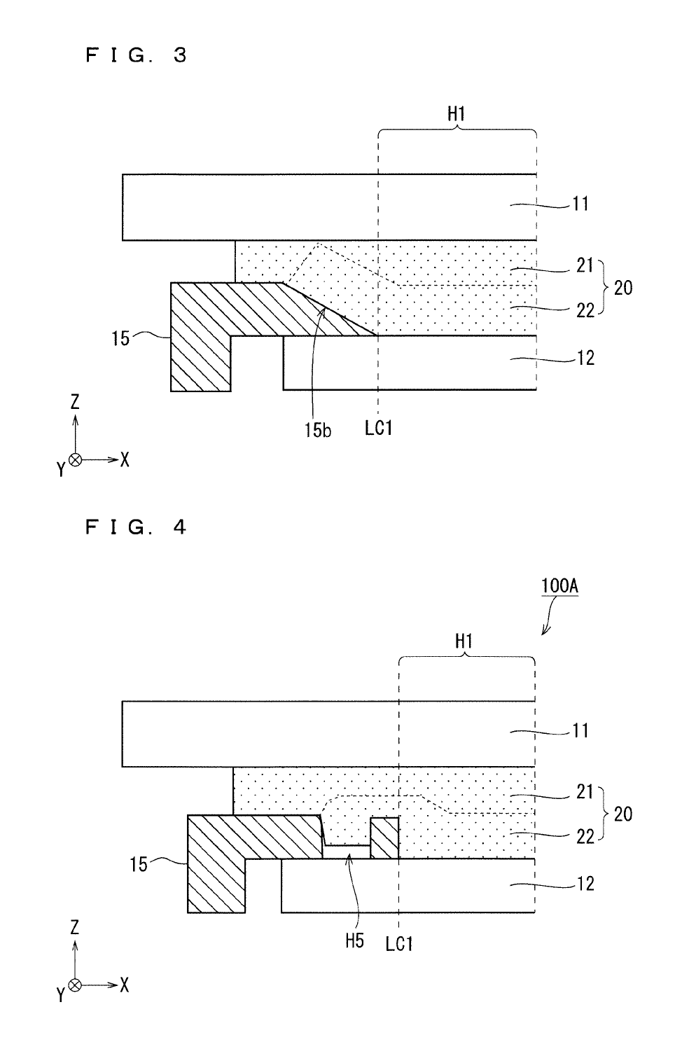

This embodiment is not limited to the constitution where the stress reducing portion formed on the opening-side edge portion is the recessed portion 15A. For example, as shown in FIG. 3, an inclined portion 15b constituting the stress reducing portion may be formed on the opening-side edge portion. By adopting such a constitution, it is possible to acquire the same advantageous effects as the above-mentioned advantageous effects obtained by forming the recessed portion 15A.

### Second Preferred Embodiment

FIG. 4 is a cross-sectional view of a display device 100A according to a second preferred embodiment of the present invention. Referring to FIG. 4, the display device 100A differs from the display device 100 shown in FIG. 2 with respect to the constitution of a stress reducing portion formed on an opening-side edge portion of the frame 15. Other constitutions of the display device 100A are substantially equal to the corresponding constitutions of the display device 100 and hence, the detailed description of other constitutions is not repeated. Hereinafter, the display device 100A is described mainly with respect to points which make the display device 100A different from the display device 100.

In this preferred embodiment, as shown in FIG. 4, hole portions H5 constituting stress reducing portions are formed in the opening-side edge portion of the frame 15. The hole portion H5 is a through hole portion.

Due to the above-mentioned constitution, the display device 100A can also acquire the substantially same advantageous effects as the first preferred embodiment. That is, due to the presence of the hole portion H5, a member stress applied to the opening-side edge portion is reduced (alleviated) by an amount corresponding to a volume of the hole portions H5. Accordingly, some of the member stress applied in the Z axis direction in FIG. 4 is reduced.

Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

Due to the presence of the hole portions H5, a member stress generated between the adhesive member 21 and the adhesive member 22 is also reduced. Accordingly, it is possible to prevent the intrusion of air bubbles (small spaces) between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the presence of the hole portions H5, a member stress generated in the adhesive member 22 is also reduced. Accordingly, in adhering the adhesive member 21 and the adhesive member 22 to each other, it is possible to prevent the presence of air bubbles between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the above-mentioned constitution, the display device 100A can easily realize the display of an image with high quality.

### Third Preferred Embodiment

FIG. 5 is a cross-sectional view of a display device 100B according to a third preferred embodiment of the present invention. Referring to FIG. 5, the display device 100B differs from the display device 100 shown in FIG. 2 with respect to the constitution of a stress reducing portion formed on an opening-side edge portion of the frame 15. Other constitutions of the display device 100B are substantially equal to the corresponding constitutions of the display device 100 and hence, the detailed description of other constitutions is not repeated. Hereinafter, the display device 100B is described mainly with respect to points which make the display device 100B different from the display device 100.

In the first preferred embodiment or in the second preferred embodiment, there is a possibility that burrs are formed from the frame 15 at the time of forming the recessed portion 15A, the inclined portion 15b or the hole portions H5 on the opening-side edge portion of the frame 15. When burrs are formed, the quality of an image displayed by the display device is remarkably lowered.

In view of the above, in this preferred embodiment, as shown in FIG. 5, a groove portion 15d constituting the stress reducing portion is formed on the opening-side edge portion of the frame 15. Due to such a constitution, even when burrs are formed at the time of forming the groove portion 15d, there is no possibility that the burrs are brought into contact with the display surface 12a of the display panel 12. Accordingly, it is possible to prevent the lowering of the quality of image displayed by the display device 100B.

Due to the above-mentioned constitution, the display device 100B can also acquire the substantially same advantageous effects as the first preferred embodiment. That is, due to the presence of the groove portion 15d, a member stress applied to the opening-side edge portion is reduced (alleviated) by an amount corresponding to a volume of the groove portion 15d. Accordingly, some of the member stress applied in the Z axis direction in FIG. 5 is reduced.

Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

Due to the presence of the groove portion 15d, a member stress generated between the adhesive member 21 and the adhesive member 22 is also reduced. Accordingly, it is possible to prevent the intrusion of air bubbles (small spaces) between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the presence of the groove portion 15d, a member stress generated in the adhesive member 22 is also reduced. Accordingly, in adhering the adhesive member 21 and the adhesive member 22 to each other, it is possible to prevent the presence of air bubbles between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Further, in this preferred embodiment, even when burrs are formed at the time of forming the groove portion 15d, there is no possibility that the burrs are brought into contact with the display surface 12a of the display panel 12. Accordingly, it is possible to prevent the lowering of the quality of image displayed by the display device 100B.

Due to the above-mentioned constitution, the display device 100B can easily realize the display of an image with high quality.

### Fourth Preferred Embodiment

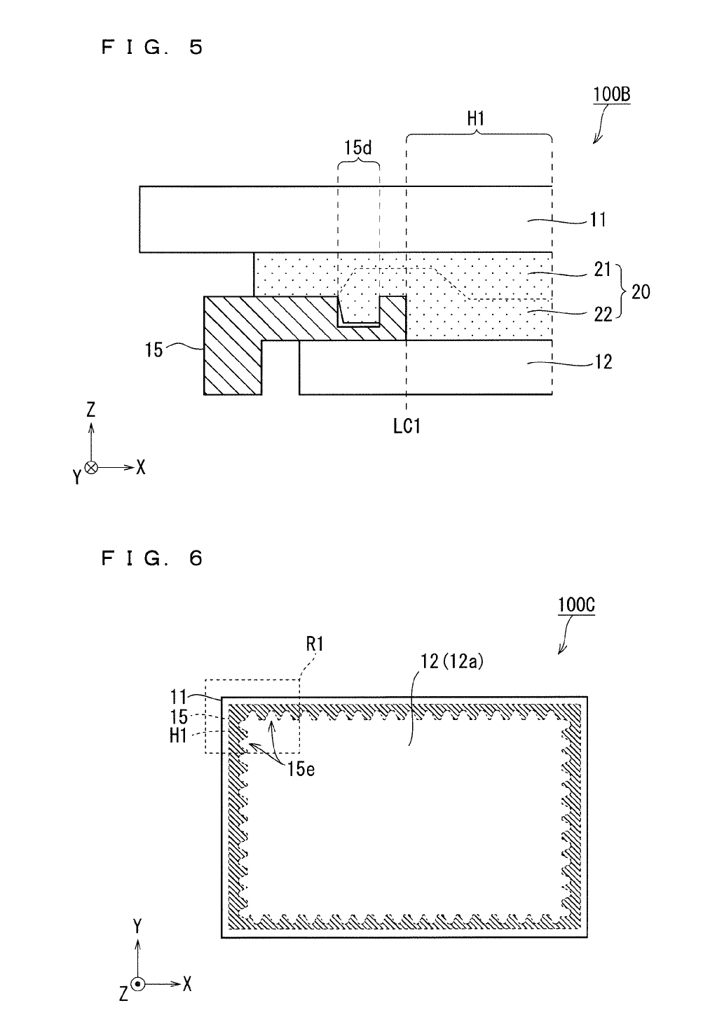

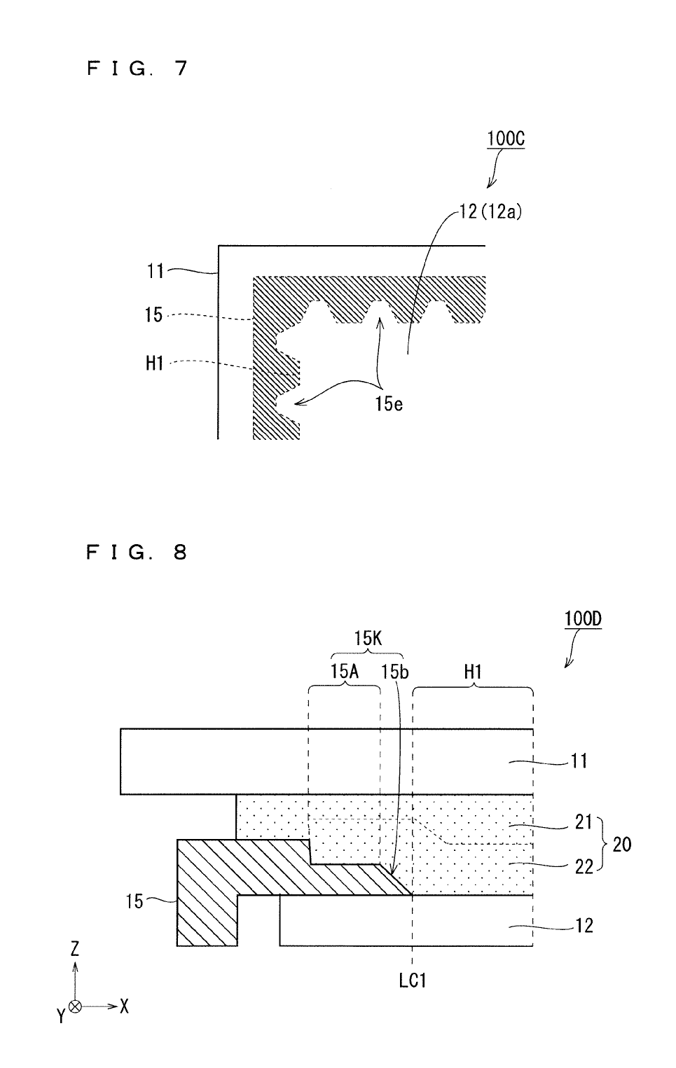

FIG. 6 is a plan view of a display device 100C according to a fourth preferred embodiment of the present invention. FIG. 7 is a partial enlarged view of the display device 100C according to the fourth preferred embodiment of the present invention. To be more specific, FIG. 7 is an enlarged view of a region R1 in FIG. 6.

Referring to FIG. 6 and FIG. 7, the display device 100C differs from the display device 100 shown in FIG. 1 with respect to the constitution of a stress reducing portion formed on an opening-side edge portion of the frame 15. Other constitutions of the display device 100C are substantially equal to the corresponding constitutions of the display device 100 and hence, the detailed description of other constitutions is not repeated. Hereinafter, the display device 100C is described mainly with respect to points which make the display device 100C different from the display device 100.

In this preferred embodiment, as shown in FIG. 6 and FIG. 7, a cutout portion 15e constituting the stress reducing portion is formed on the opening-side edge portion of the frame 15. The cutout portions 15e are formed on the opening-side edge portion of the frame 15 in the direction along an XY plane. The display device 100C shown in FIG. 6 and FIG. 7 has the constitution where a plurality of cutout portions 15e are formed on all four sides of the rectangular opening-side edge portion of the frame 15 shown in FIG. 1.

Due to the above-mentioned constitution, the display device 100C can also acquire the substantially same advantageous effects as the first preferred embodiment. That is, due to the presence of the cutout portions 15e, a member stress applied to the opening-side edge portion is reduced (alleviated) by an amount corresponding to a volume of the cutout portions 15e. Accordingly, some of the member stress applied in the direction along the XY plane in FIG. 6 and FIG. 7 is reduced.

Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

Due to the presence of the cutout portions 15e, a member stress generated between the adhesive member 21 and the adhesive member 22 is also reduced. Accordingly, it is possible to prevent the intrusion of air bubbles (small spaces) between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the presence of the cutout portions 15e, a member stress generated in the adhesive member 22 is also reduced. Accordingly, in adhering the adhesive member 21 and the adhesive member 22 to each other, it is possible to prevent the presence of air bubbles between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the above-mentioned constitution, the display device 100C can easily realize the display of an image with high quality.

### Fifth Preferred Embodiment

FIG. 8 is a cross-sectional view of a display device 100D according to a fifth preferred embodiment of the present invention. Referring to FIG. 8, the display device 100D differs from the display device 100 shown in FIG. 2 with respect to the constitution of a stress reducing portion formed on an opening-side edge portion of the frame 15. Other constitutions of the display device 100D are substantially equal to the corresponding constitutions of the display device 100 and hence, the detailed description of other constitutions is not repeated. Hereinafter, the display device 100D is described mainly with respect to points which make the display device 100D different from the display device 100.

In this preferred embodiment, as shown in FIG. 8, a stress reducing portion 15K is formed on the opening-side edge portion of the frame 15. In the same manner as described in the first preferred embodiment, the stress reducing portion 15K has the constitution of reducing a member stress. The stress reducing portion 15K is constituted of at least two portions selected from a group consisting of a recessed portion 15A, an inclined portion 15b, a groove portion 15d, a hole portion H5 and a cutout portion 15e, for example. In FIG. 8, the stress reducing portion 15K is constituted of the recessed portion 15A and the inclined portion 15b as one example.

Due to the above-mentioned constitution, the display device 100D can also acquire the substantially same advantageous effects as the first preferred embodiment. That is, due to the presence of the stress reducing portion 15K, a member stress applied to the opening-side edge portion is reduced (alleviated) by an amount corresponding to a volume of the stress reducing portion 15K. Accordingly, some of the member stress applied in the Z axis direction in FIG. 8 is reduced.

Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

Due to the presence of the stress reducing portion 15K, a member stress generated between the adhesive member 21 and the adhesive member 22 is also reduced. Accordingly, it is possible to prevent the intrusion of air bubbles (small spaces) between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the presence of the stress reducing portion 15K, a member stress generated in the adhesive member 22 is also reduced. Accordingly, in adhering the adhesive member 21 and the adhesive member 22 to each other, it is possible to prevent the presence of air bubbles between the adhesive member 21 and the adhesive member 22 or it is possible to reduce an amount of air bubbles present between the adhesive member 21 and the adhesive member 22. Even when air bubbles are present between the adhesive member 21 and the adhesive member 22, an amount of air bubbles is small and hence, the air bubbles can be easily eliminated by performing the above-mentioned pressurization treatment.

Due to the above-mentioned constitution, the display device 100D can easily realize the display of an image with high quality.

### Sixth Preferred Embodiment

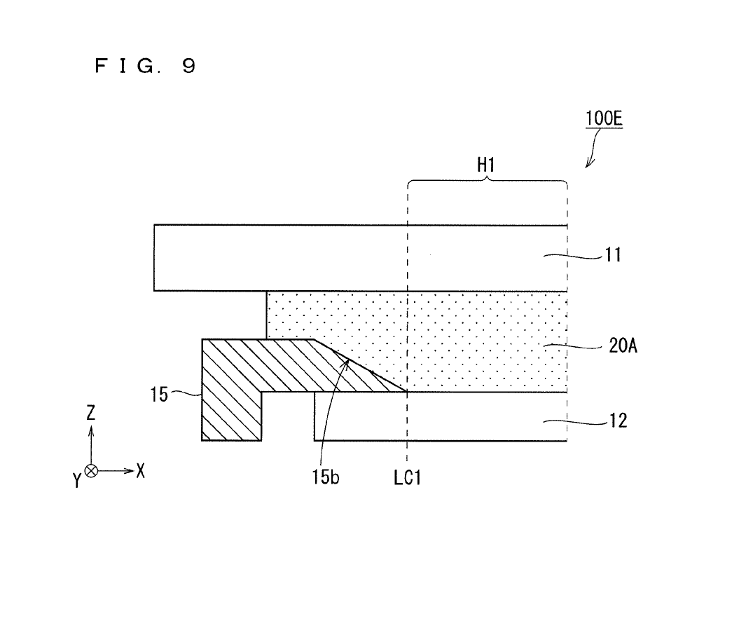

FIG. 9 is a cross-sectional view of a display device 100E according to a sixth preferred embodiment of the present invention. Referring to FIG. 9, the display device 100E differs from the display device 100 shown in FIG. 3 with respect to a point that the display device 100E includes an adhesive member 20A instead of the adhesive member 20. Other constitutions of the display device 100E are substantially equal to the corresponding constitutions of the display device 100 and hence, the detailed description of other constitutions is not repeated. Hereinafter, the display device 100E is described mainly with respect to points which make the display device 100E different from the display device 100.

Different from the adhesive member 20, the adhesive member 20A is formed of one adhesive member. The adhesive member 20A is a transparent adhesive sheet, for example. The adhesive member 20A adheres the display surface 12a of the display panel 12 and a protective cover 11 to each other. That is, as shown in FIG. 9, the adhesive member 20A is disposed between the display surface 12a and the protective cover 11 in a state that the adhesive member 20A is in contact with the display surface 12a and the protective cover 11. In the description made hereinafter, a stress generated in the adhesive member 20A due to a contact of the adhesive member 20A with the opening-side edge portion is also referred to as a member stress.

The stress reducing portion formed on the opening-side edge portion of the frame 15 may be any one of the above-mentioned recessed portion 15A, an inclined portion 15b, hole portions H5, a groove portion 15d, a cutout portion 15e and a stress reducing portion 15K. FIG. 9 shows an inclined portion 15b as one example of a stress reducing portion formed on the opening-side edge portion of the frame 15.

Due to the above-mentioned constitution, the display device 100E can also acquire the substantially same advantageous effects as the first preferred embodiment. That is, due to the presence of the stress reducing portion formed on the opening-side edge portion, a member stress applied to the opening-side edge portion is reduced (alleviated) by an amount corresponding to a volume of the stress reducing portion. Accordingly, some of the member stress applied in the Z axis direction in FIG. 9 is reduced.

Accordingly, it is possible to prevent the formation of small spaces between the protective cover 11 and the display panel 12 or it is possible to reduce an amount of small spaces present between the protective cover 11 and the display panel 12. Even when the small spaces are present between the protective cover 11 and the display panel 12, an amount of small spaces is small and hence, the small spaces can be easily eliminated by performing the above-mentioned pressurization treatment.

Due to the presence of the stress reducing portion, a member stress generated in the adhesive member 20A is also reduced. Accordingly, at the time of adhering the protective cover 11 and the display panel 12 to each other, it is possible to prevent the presence of air bubbles in the adhesive member 20A or it is possible to reduce an amount of air bubbles present in the adhesive member 20A. Even when air bubbles are present in the adhesive member 20A, an amount of air bubbles is small and hence, the air bubbles can be easily eliminated by performing the above-mentioned pressurization treatment.

Due to the above-mentioned constitution, the display device 100E can easily realize the display of an image with high quality.

(Modification) The display devices 100, 100A, 100B, 100C, 100D, and 100E are not limited to a liquid crystal display device, and display devices adopting other systems may be also used as the display devices 100, 100A, 100B, 100C, 100D, and 100E. The display device 100 may be a plasma display device, for example. In this case, the display panel 12 may be a plasma display panel. The display device 100 may also be an organic EL (Electroluminescence) display device, for example. In this case, the display panel 12 may be an organic EL panel.

The adhesive member 20 is not limited to a solid adhesive sheet. The adhesive member 20 may be a transparent adhesive member which is obtained by curing or semi-curing a resin in a liquid form.

While the invention has been shown and described in detail, the foregoing description is in all aspects illustrative and not restrictive. It is therefore understood that numerous modifications and variations can be devised without departing from the scope of the invention.

What is claimed is:

1. A display device comprising:
a display panel having a display surface on which an image is displayed;
a frame which holds said display panel, said frame having an opening formed therein, said opening being formed so as to expose said display surface to the outside of said frame as viewed in a plan view;
a protective cover having light transmitting property and formed so as to cover said display surface; and
an adhesive member having light transmitting property and disposed between said display surface and said protective cover such that said adhesive member is in contact with said display surface and said protective cover, wherein
said adhesive member is disposed over a region ranging from the inside of said opening to an upper surface of an opening-side edge portion which is an edge portion of said frame and is in contact with the opening, and
a stress reducing portion which reduces a stress generated in the adhesive member due to a contact of said adhesive member with the opening-side edge portion is formed on said opening-side edge portion.

2. The display device according to claim 1, wherein
said opening-side edge portion is a region ranging from a position of said frame which is in contact with said opening to an edge of said adhesive member disposed on said upper surface, or a region corresponding to an edge portion of said adhesive member disposed on the upper surface of the frame.

3. The display device according to claim 1, wherein
a thickness of said adhesive member is equal to or more than a thickness of a portion of said opening-side edge portion where said stress reducing portion is not formed.

4. The display device according to claim 1, wherein
a size of said adhesive member as viewed in a plan view is larger than a size of said opening as viewed in a plan view.

5. The display device according to claim 1, wherein
said adhesive member is constituted of a first adhesive member and a second adhesive member,
said first adhesive member is in contact with said protective cover,
a size of said first adhesive member as viewed in a plan view is larger than a size of said opening as viewed in a plan view,
said second adhesive member is in contact with said display surface through said opening, and
a size of said second adhesive member as viewed in a plan view is larger than the size of said opening as viewed in a plan view.

6. The display device according to claim 5, wherein
a thickness of said second adhesive member is equal to or more than a thickness of a portion of said opening-side edge portion where said stress reducing portion is not formed.

7. The display device according to claim 1, wherein
a thickness of a portion of said opening-side edge portion where said stress reducing portion is formed is smaller than a thickness of a portion of said opening-side edge portion where said stress reducing portion is not formed.

8. The display device according to claim 1, wherein said stress reducing portion is a recessed portion.

9. The display device according to claim 1, wherein said stress reducing portion is an inclined portion.

10. The display device according to claim 1, wherein said stress reducing portion is a groove portion.

11. The display device according to claim 1, wherein said stress reducing portion is a hole portion.

12. The display device according to claim 1, wherein said stress reducing portion is a cutout portion.

13. The display device according to claim 1, wherein
said stress reducing portion is constituted of at least two portions selected from a group consisting of the recessed portion, the inclined portion, the groove portion, the hole portion and the cutout portion.
